(19) United States
(12) Patent Application Publication
(10) Pub. No.: US 2026/0194610 A1
(43) Pub. Date: Jul. 9, 2026

(54) DNP PROBE HEAD FOR HIGH RESOLUTION, LIQUID-STATE NMR

(71) Applicants: Bruker BioSpin GmbH & Co. KG, Ettlingen (DE); Max-Planck-Gesellschaft zur Förderung der Wissenschaften e.V., München (DE); Thomas Keating Ltd, West Sussex (GB)

(72) Inventors: Thorsten MARQUARDSEN, Karlsruhe (DE); Marina BENNATI, Göttingen (DE); Igor TKACH, Göttingen (DE); Marcel LEVIEN, Göttingen (DE); Tomas ORLANDO, Göttingen (DE); Luming YANG, Göttingen (DE); Alisa LEAVESLEY, Charlottesville, VA (US); Richard WYLDE, West Sussex (GB)

(21) Appl. No.: 19/134,419

(22) PCT Filed: Nov. 30, 2023
(86) PCT No.: PCT/EP2023/083825

§ 371 Date: May 30, 2025

(30) Foreign Application Priority Data
Dec. 1, 2022 (DE) 10 2022 212 952.0

(51) Int. Cl. G01R 33/345; G01N 24/08; G01R 33/30; G01R 33/31; G01R 33/44

(52) U.S. Cl. CPC G01R 33/345; G01N 24/082; G01R 33/307; G01R 33/31; G01R 33/445

(57) ABSTRACT

An NMR probe head (1) for performing high-resolution, liquid-state DNP-NMR comprises a corrugated waveguide (3) for mw transmission, arranged along a longitudinal axis Z of the probe head; a system of at least two of mw reflecting mirrors (4-7) for mw beam transmission, focusing and reshaping the beam to match for a sample geometry; at least one RF coil (11,12) for NMR detection mounted in a way to allow mw passage to the sample area, characterized by a cooling system comprising a flow dewar tube (8) for feeding cryogenic fluid mounted at the side of the probe head and parallel to the corrugated waveguide and a thermally isolated sample chamber (26) surrounded by a chamber dewar (9); a sample spinning arrangement being configured to achieve uniform irradiation over a sample volume, to increase the sample volume under mw irradiation, and to reduce sample heating; a sample assembly (13) comprising concentric circular tubes or rods (15, 16) forming constraints for a sample layer (14). This arrangement is capable of exciting in particular even large sample volumes up to ~40 μL.

### FIELD OF THE INVENTION AND CLOSEST PRIOR ART

The present invention relates to an NMR (=nuclear magnetic resonance) probe head being configured for performing high-resolution, liquid-state DNP (=dynamic nuclear polarization)-NMR and comprising:
a corrugated waveguide for mw (=microwave) transmission, arranged along a longitudinal axis Z of the probe head,
a system of at least two of mw reflecting mirrors for mw beam transmission, focusing and reshaping to match for a sample geometry,
at least one RF coil for NMR detection mounted in a way to allow mw passage to the sample area.

Such a DNP-NMR probe head including associated mw and RF equipment is e.g. known from Yoon, D., et al., High-Field Liquid-State Dynamic Nuclear Polarization in Microliter Samples. Analytical Chemistry, 2018. 90(9): p. 5620-5626 (=Reference [11]).

### BACKGROUND OF THE INVENTION AND STATE OF THE ART

NMR is an established technique to obtain structural information in chemistry, physics and molecular biology. The method is based on detection of magnetic nuclei, energies of which split in a static magnetic field (specified as B₀). If such nuclei are exposed to radio-frequencies (RF), a resonant absorption can be observed, and the NMR signal at nuclear Larmor frequencies can be recorded. However, a small energy splitting, and thus an inherently small spin-state population difference (so called spin polarization), results in limited NMR sensitivity. The lack of sensitivity can be improved by applying stronger external magnetic fields, however to a finite extent and at very high costs. Another way to increase the sensitivity is a method called dynamic nuclear polarization (DNP), see Reference [1]. It takes advantage of a larger spin polarization of unpaired electrons, which can be transferred to the nuclear spins using double- or multiple-resonance setups, providing combined microwave (MW) and RF irradiation. DNP offers impressive NMR signal enhancements in solids, and thus is extensively used in solid-state, magic-angle spinning (MAS), and in so-called dissolution DNP-NMR.

In liquids, DNP is governed by the Overhauser effect, see References [2, 3], and is performed by mixing the so-called polarizing agent (PA), usually a nitroxide radical, with the target molecule for NMR. The electron spin resonance (ESR) transitions of the PA are saturated at resonance microwave frequencies and the enhanced NMR signal of the target is detected in the RF range. Despite the fact that NMR in liquids is the most widespread art of NMR spectroscopy, DNP in liquids is not yet established in NMR. The major reason is that one of the crucial parameters of the Overhauser effect is the saturation factor (s), which depends on several different parameters, but mainly on the microwave magnetic field strength (B₁), and thus on the applied mw power. However, in liquids, particularly in polar solvents, the microwave irradiation is severely absorbed. The effect is due to high and frequency-dependent dielectric losses of most liquid media. This causes, on the one hand, strong sample heating (scaled by the provided mw power), and on the other hand, reduction of the B₁ strength. Heating of the sample is particularly detrimental since it can destroy the molecules under study and deteriorate NMR spectra quality. The problem can be alleviated to a certain extent by using microwave resonators, but those require conducting materials in close vicinity to the sample, which destroys the static field homogeneity. This causes substantial NMR line broadening, and thus a spectral resolution loss. Moreover, microwave resonators considerably decrease the sample volumes, counteracting the sensitivity gain. The latter drawback is particularly critical at high magnetic fields (like those applied for this invention), since the size of the resonators, scaled by the wavelength of used microwaves, is dramatically reduced.

Another challenge arises from the intrinsic DNP mechanism, which is based on cross-relaxation between electron and nuclear spins, with the efficiency decreasing upon increase of the static magnetic field B₀. Furthermore, the cross-relaxation is often driven by two mechanisms, the dipolar and scalar relaxation, delivering opposite signs of the enhancement and thus cancelling each other, particularly at low and medium magnetic fields, where the dipolar interaction is still considerably high. However, we and other recently demonstrated that the scalar mechanism survives at high magnetic fields, which is relevant for modern NMR, see References [3-8]. Therefore, the establishment of liquid-state DNP is currently limited by the availability of a suited probe head design.

Attempts to provide a high-field/frequency, liquid-state DNP-NMR probe head have been already described in References [9-15]. These reports disclose valuable designs and technical solutions, however mainly adapted for an efficient microwave excitation, and not for high-resolution NMR. Thus, even though they report on interesting DNP mechanistic results, those probe heads cannot be used in routine high-resolution NMR spectroscopy. Particularly, the resonator-based designs all show the above-mentioned drawbacks of small sample volumes and loss of spectral resolution, see References [12-14, 16, 17].

For example, Reference [11] already cited above describes a planar probe head suitable for liquid state DNP on ³¹P and protons at 9.2 T which, however, is only adapted for comparatively small sample volumes. Despite the non-resonant configuration, it affords reasonably high B₁-strengths at high input power (≈2.5 G at 70 W input). The irradiated sample volume is close to 5 μL (considering the reported beam waist of 5 mm and the penetration depth of ≈60 μm in water at 5° C.), whereas the total sample size detectable by NMR is around 10 μL. Additionally, an effective sample cooling is provided by using a gold-plated, high thermal conductivity AlN support. Even though the probe shows high microwave and cooling efficiency, it contains an excessive amount of conducting material in close vicinity to the sample. As a result, the reported proton NMR line widths are in the range of ~10 ppm at 9.2 T, which is far from today's high-resolution NMR standards.

A similar setup is described in Reference [9]. It comprises an RF transducer for NMR detection, which together with a grid polarizer, partially transparent for microwaves, forms a quasi-resonant, Fabry-Pérot (FP) configuration. The setup is motivating and can be manufactured in different arrangements, however, as in the previous example, contains conducting materials close to the sample, leading to field homogeneity perturbations.

The same holds for Reference [10], which describes another resonant setup, where NMR detection is provided by a conducting strip line, forming at the same time a portion of a Fabry-Pérot resonator. In spite of the double resonance configuration and unconventional RF coil design, the probe head is characterized by both high sensitivity for NMR and high microwave efficiency for DNP. Furthermore, the design is beneficial since it shows an improved sample cooling capability. However, it again uses field-disturbing materials close to the sample, and the sample volumes are strongly reduced. Therefore, the setup is restricted to only special applications.

To overcome the above drawbacks, we designed a liquid-state DNP-NMR probe head, which permits microwave excitation of large sample volumes, however, under condition of optimized NMR performance, i.e. at controlled sample heating and no compromise for NMR resolution. Our recent studies (see References [4, 7]), as well as reports of other groups (see References [6, 16]) inferred that the B₁ magnetic fields, required to saturate the EPR transitions of common polarizers, should be in the range of 2-3 G. This fields can be also achieved in a non-resonance mw setup by using a high-power source (like here, a gyrotron, output power >10 W), but a special sample geometry is required to allow for mw penetration across the sample, i.e. the sample thickness has to be shorter than the mw penetration depth. Furthermore, an efficient cooling, counterbalancing the sample heating, must be implemented. In this case, a non-resonant microwave setup is advantageous since allows for large sample volumes and does not require introduction of field disturbing materials (i.e. metals), particularly in close vicinity to the sample. Such setup should not affect the NMR resolution, and should be easier to handle in routine experiments. It is the underlying purpose of this invention to provide a DNP probe head for routine and high-resolution NMR spectroscopy.

### Objectives of the Invention

It is an objective of the invention to provide a liquid-state DNP-NMR probe head for routine NMR being capable of exciting in particular even large sample volumes up to ~40 μL. Preferably, the probe head should be designed to operate at microwave frequencies close to 263 GHz for DNP, and should be suitable for standard double resonance NMR at fields close to 9.4 T. Nevertheless, the design approach should be easily adaptable for operation at higher mw frequencies (up to THz) and NMR fields.

It is further preferred to provide a DNP-NMR probe head wherein the microwave components, particularly focusing mirrors, and the sample assembly do not contribute to the static magnetic field inhomogeneity and thus allow high-resolution NMR measurements.

Furthermore, it is an objective of the invention to provide a DNP-NMR probe head, wherein the mw is transmitted through the liquid sample and its temperature can be controlled to avoid boiling of the sample.

Finally, it is an objective of the invention to provide a DNP-NMR probe head, wherein the sample can be rotated during the experiment, and thus the effective sample volume exposed to microwave is significantly increased.

### SUMMARY OF THE INVENTION

The objectives are achieved by a design of a generic NMR probe head as defined on the top page above, which is characterized by
a cooling system comprising a flow dewar tube for feeding cryogenic fluid mounted at the side of the probe head and parallel to the corrugated waveguide and a thermally isolated sample chamber surrounded by a chamber dewar,
a sample spinning arrangement being configured to achieve uniform irradiation over a sample volume, to increase the sample volume under mw irradiation, and to reduce sample heating,
a sample assembly comprising concentric circular tubes or rods forming constraints for a sample layer.

The DNP-NMR probe head according to the present invention is particularly optimized for high-resolution DNP-NMR, which operates at EPR/DNP frequencies, in particular close to 263 GHz.

To perform DNP, the probe head contains microwave components including a corrugated downtaper, corrugated WG (=waveguide), and a system of microwave-reflecting mirrors. The mw (=microwave) beam from a source is transferred by the taper and the corrugated WG to the system of the mirrors used to focus, transform, and deliver the mw beam further to the sample assembly. The mirrors are mounted inside the thermally isolated sample chamber, close to the sample assembly and the NMR coils.

The sample arrangement is considered to be a key subject of the present invention. The liquid sample is confined by two concentric tubes or rods of circular cross-section and preferably made of quartz thus forming a thin layer, the thickness of which is chosen depending on the sample dielectric properties, and not exceeds the mw penetration depth.

Furthermore, the sample assembly is spinning around Z axis, which is implemented, first, to increase the area of the sample being exposed to mw, and second, to avoid overheating of the sample which is under mw exposition. According to the invention, the sample spinning arrangement is configured to achieve uniform irradiation over a sample volume, to increase the sample volume under mw irradiation, and to reduce sample heating. This sample rotation approach increases the effective sample area exposed by microwave and improves the cooling efficiency under microwave excitation.

Furthermore, the use of a thin sample layer confined by the tubes or rods leads to enhancement of the B₁ field at the sample position, which can be rationalized by an increased standing wave ratio caused by interferences with the reflected wave at the interface of two dielectric media with different permittivity values.

To additionally protect the sample from overheating, the probe head accommodates cooling units designed to deliver the cryogenic fluid, e.g. cold N₂ gas, to the sample. It comprises a dewar preferably made of glass and a thermally insulated sample chamber. The cryogenic fluid is injected into the dewar, distributed inside the sample chamber and from there removed away to provide a constant flow over the sample surface.

In essence, the invention has the following advantages:
1) The probe head is adapted for high-resolution DNP-NMR on large liquid sample volumes, which are still protected from overheating.
2) The design permits microwave excitation without contributing to magnetic field inhomogeneities, thus NMR resolution is not affected.
3) The MW and cooling units can be easily installed in existing standard, liquid-state NMR probe heads, thus opening the opportunity to widespread DNP-NMR measurements.

### PREFERRED EMBODIMENTS AND FURTHER DEVELOPMENTS OF THE INVENTION

The thickness of the—comparatively thin—sample layer in the NMR probe head according to the invention can be varied, depending on the permittivity E of the solvent, the sample temperature, and the mw frequency. In preferred embodiments, the thickness of the sample layer is between 0,25Δ and 1,25Δ, where Δ is the penetration depth of the mw in the liquid sample medium.

Preferably, the thickness of the sample layer does not exceed the penetration depth Δ of the mw in the liquid sample medium.

In particularly preferred embodiments of the NMR probehead according to the invention, the sample assembly comprises two concentric circular tubes or rods. This arrangement is advantageous since it allows forming a sample layer with a desired thickness, not exceeding the mw penetration depth Δ, and depending on the sample dielectric properties. Furthermore, the cylindrical sample geometry is favorable when spinning the sample around Z axis, the capability which is particularly implemented 1) to increase the sample volume excited by mw, and 2) to reduce sample heating.

In a preferred further development of this embodiment, two or more concentric tubes or rods can be used to have more than one sample layer, each with thickness not exceeding Δ/n (n is the number of the layers), and thus to further enlarge the sample volume.

In a preferred further development of this embodiment, the sample assembly is made of a material with low mw absorption, preferably of quartz or any mw-transparent material. This is required 1) to minimize mw losses, and 2) further reduce sample heating due to losses in assembly tubes (rods).

Also advantageous is an embodiment wherein four mw reflecting mirrors are provided transmitting the mw to the sample assembly while keeping the proper B₁ magnetic field polarization and forming the beam profile optimally distributed over the sample geometry to reduce its heating and increase the efficiency of mw excitation. The arrangement with four mw mirrors permits usage of the design wherein the corrugated waveguide assembly is mounted along Z axis, which is advantageous considering space constraints in the NMR probehead.

Preferred are embodiments wherein the mirrors have curvatures based on conic sections or they may be shaped quasi-elliptical, in particular having curvatures providing the efficient focusing and beam passage. Additionally, the mirror curvatures and their relative arrangement are designed in a way to reshape the radial beam profile in order to match sample geometry.

In another embodiment of the invention, the system of mw reflecting mirrors for mw beam transmission, focusing and reshaping the beam, comprises four mirrors being positioned at distances 0 mm, 17.25 mm, 42.5 mm, and 34.50 mm from Z axis (last two values measured at the height of the coil centra) to form the beam profile optimally distributed over the sample geometry. Further advantage is that all four mirrors are mounted far enough from the sample assembly, and do not contribute to the static field inhomogeneities at the sample position.

Another preferred embodiment provides that the mirrors are manufactured from Macor® ceramic coated in particular by gold for minimizing magnetic field distortions around the sample and keeping high homogeneity of the static magnetic field B₀.

In a preferred further development of this embodiment, the coated layer of the mirrors has a thickness of between 3δ and 7δ, where δ is the skin depth in gold at room temperature (~0.15 μm), in particular to keep high conductivity of a skin layer for mw frequencies close to 263 GHz, but still minimize magnetic field distortions around the sample. Usage of gold provides another advantage which is a possibility to reduce the thickness of the metallic layer due to high conductivity, and high oxidation resistance of the material.

Also advantageous are embodiments wherein the mirrors are designed in the way to transmit the mw beam with a proper B₁ magnetic field polarization, which is orthogonal to the static magnetic field, B₀, to saturate ESR transitions for DNP, and in the way to minimize magnetic field distortions around the sample and keep high homogeneity of the static magnetic field, B₀, which is needed for high resolution NMR.

In another embodiment of the invention, two RF coils are provided, one of which is matched for a second resonating frequency for measuring other nuclei or for ²H-locking. Furthermore, usage of two RF coils is advantageous since it allows performing nuclear-coherence 2D experiments, and hetero-nuclear decoupling.

Further preferred are embodiments wherein at least one shielding tube is arranged concentrically around the sample assembly to conduct the cryogenic fluid. In particular, two shielding tubes are provided to support NMR coils and configured to increase the efficiency of the sample cooling. The shielding tubes also prevent possible vibration of the coils under gas flow.

In particularly preferred embodiments of the invention, the corrugated waveguide is designed for minimizing mw losses in a desired frequency range and for keeping required polarization of the microwave magnetic field B₁. Moreover, the waveguide is designed in a way to minimize B₀ magnetic field distortions around the sample, i.e. it is mounted sufficiently far from the sample area.

Especially preferred is an embodiment of the invention, in which the cooling system comprises a device for controlling the sample temperature in the way to minimize heating of the sample during mw excitation and to stabilize temperature of the sample at the particular value.

Also within the scope of the present invention are embodiments which are designed for performing high-resolution 1 D and 2D DNP-enhanced NMR spectroscopy on magnetic nuclei exhibiting the Overhauser effect with a radical polarizing agent, in particular using a non-resonant microwave setup. The non-resonant setup will not affect the NMR resolution, and is easier to handle in routine experiments.

### BRIEF DESCRIPTION OF THE DRAWINGS

Further details and advantages of the invention will be described in the following, with reference to the attached drawings, which are shown in:

FIG. 1 Perspective view of the DNP-NMR probe head according to a preferred embodiment.

FIG. 2 Simplified view of the microwave and cooling components of the DNP-NMR probe head.

FIG. 3 Simplified view of the corrugated WG assembly and the mirror arrangement.

FIG. 4 Sectional view of the mirror and sample arrangement indicating the microwave path and sample exposition.

FIG. 5 Simplified sectional view of the mirror arrangement indicating the microwave path and sample exposition.

FIG. 6 Simplified view of the cooling components including thermally isolated sample chamber.

FIG. 7 Sectional view of the thermally isolated sample chamber with the indication of the N₂ gas flow around the sample assembly.

FIG. 8 CST model used for microwave simulations (a), and different sectional views of the microwave B₁-field pattern at 263.3 GHz and phase φ=0 while simulating with water as a solvent (b),(c),(d).

FIG. 9 NMR coils and their arrangement with respect to the microwave beam represented by the Z-axis orthogonal section of the CST simulations performed with the water sample.

FIG. 10 NMR coils and their arrangement with respect to the microwave beam represented by the Y-axis orthogonal section of the CST simulations performed with the water sample.

FIG. 11 Graphs indicating the foreseen microwave field strength along Z axis at the front- and the back-side of the sample while simulating with three different solvents (CCl₄, CHCl₃, and water).

FIG. 12 Boltzmann and DNP-enhanced ¹³C-NMR spectra recorded on a sample containing both CCl₄ and ¹³CHCl₃ in a mixture with ¹⁵N-d₁₆-4-oxo-TEMPO. Sample composition: 200 mM ¹³CHCl₃ dissolved in natural-abundant CCl₄ with 10 mM ¹⁵N-d₁₆-4-oxo-TEMPO. NS stands for number of scans. Upper inset: applied pulse sequence.

FIG. 13 a) Applied DNP pulse sequence with ¹H decoupling; b) Boltzmann (mw off) and DNP-enhanced (mw on) spectra of ~500 mM natural abundance fluorobenzene doped with 25 mM-¹⁵N-d₁₆-4-oxo-TEMPO in CCl₄ with zoom-in views on the c) Cₒᵣₜₕₒ, and d) Cₘₑₜₐ positions. NS stands for number of scans.

FIG. 14 Total Correlation (TOCSY) 2D spectra on ¹³C₆-C₆HC₅I in CCl₄ under DNP conditions: a) Structure of ¹³C₆-C₆H₅I indicating the magnetization transfer for the Cᵢₚₛₒ position; b) TOCSY pulse sequence; c) 2D DNP TOCSY spectrum with an independently measured 1D DNP spectrum of the same sample as a guide on the ω₁ and ω₂ dimension; d) Boltzmann TOCSY spectrum with an independently measured 1D Boltzmann spectrum of the same sample as a guide on the ω₁ and ω₂ dimension. Sample composition: ~500 mM ¹³C₆-C₆H₅I and ~25 mM ¹⁵N-TN-d₁₆. NS stands for number of scans.

FIG. 15 Boltzmann (mw off) and DNP-enhanced (mw on) ¹³C-NMR spectra of sodium pyruvate-3-¹³C in a water:glycerol (9:1) mixture with 25 mM ¹⁵N-d₁₆-4-oxo-TEMPO. NS stands for number of scans. Upper inset: applied pulse sequence.

### DETAILED DESCRIPTION OF THE INVENTION

The present invention relates to an NMR probe head (1), which includes microwave reflecting and focusing mirrors (4, 5, 6, 7) to perform DNP-enhanced NMR in liquids. More specifically, the invention relates to an NMR probe head configured for a routine, high-resolution DNP-NMR on large (tens of microliters) liquid sample volumes. Furthermore, the probe head includes an efficient cooling system (8, 9, 10) to alleviate sample heating during microwave excitation.

The DNP-NMR probe head according to the present invention is particularly optimized for high-resolution DNP-NMR, which operates at EPR/DNP frequencies close to 263 GHz. The design is based on a commercially available wide bore, two-channel liquid state NMR probe head (Bruker Biospin). For NMR detection, the probe head contains two saddle coils (11, 12) close to the sample. The coils can be tuned and matched on two channels to resonance (Larmor) frequencies of ¹H, ¹⁹F, ³¹P ¹³C, ¹⁵N, and ²H, which at the given NMR field B₀=9.4 T are v≈400 MHz, ≈390 MHz, ≈162 MHz, ≈100 MHz, ≈41 MHz, and ≈61 MHz, respectively. The sample tube assembly (13) is placed inside the NMR coils axially to the static magnetic field, B₀.

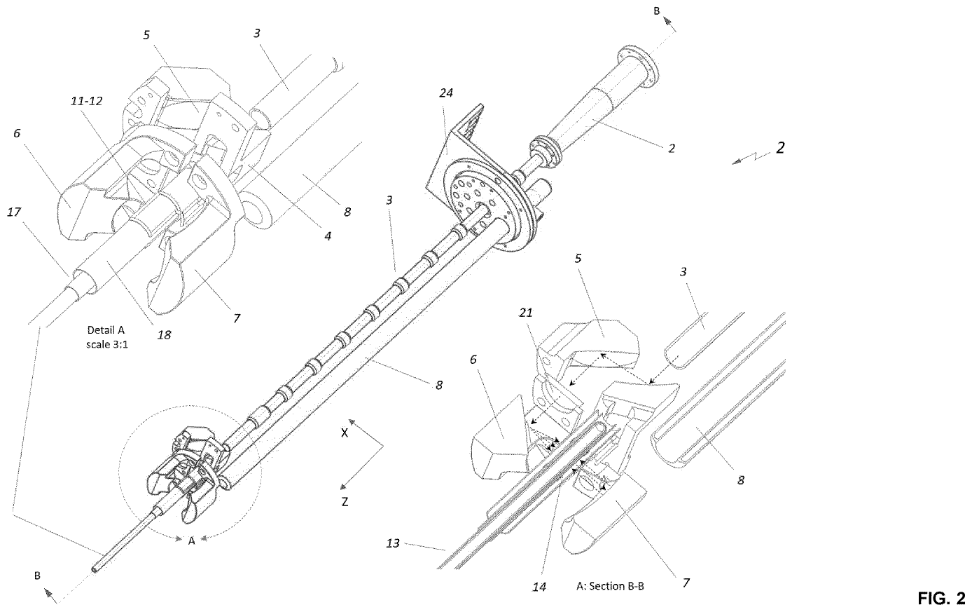

To perform DNP, the probe head contains microwave components including a corrugated downtaper (2), corrugated WG (=waveguide) (3), and a system of 4 (four) microwave-reflecting mirrors (4, 5, 6, 7). The mw beam from a source (here, gyrotron) is transferred by the taper (2) and the corrugated WG (3) to the system of the mirrors (4, 5, 6, 7) used to focus, transform, and deliver the microwave beam further to the sample assembly (13). Specifically, the system of the mirrors (4, 5, 6, 7) is designed in a way to reshape the input Gaussian beam (TEM₀₀-mode) into an elongated beam by expanding the microwave energy over the elongated sample geometry (≈8×5 mm²) (see FIGS. 2, 4, 5, 8). The mirrors (6) and (7) are mounted inside the thermally isolated sample chamber, close to the sample assembly (13) and the NMR coils (11, 12).

The sample arrangement is considered to be a key subject of the invention. The liquid sample is confined by two concentric quartz tubes (15, 16) thus forming a thin layer, the thickness of which is chosen depending on the sample dielectric properties, and not exceeds the mw penetration depth. Furthermore, the sample assembly is spinning around Z axis, which is implemented, first, to increase the area of the sample being exposed to mw, and second, to avoid overheating of the sample which is under mw exposition. Furthermore, the use of a thin sample layer confined by quartz tubes leads to enhancement of the B₁ field at the sample position, which can be rationalized by an increased standing wave ratio caused by interferences with the reflected wave at the interface of two dielectric media with different permittivity values.

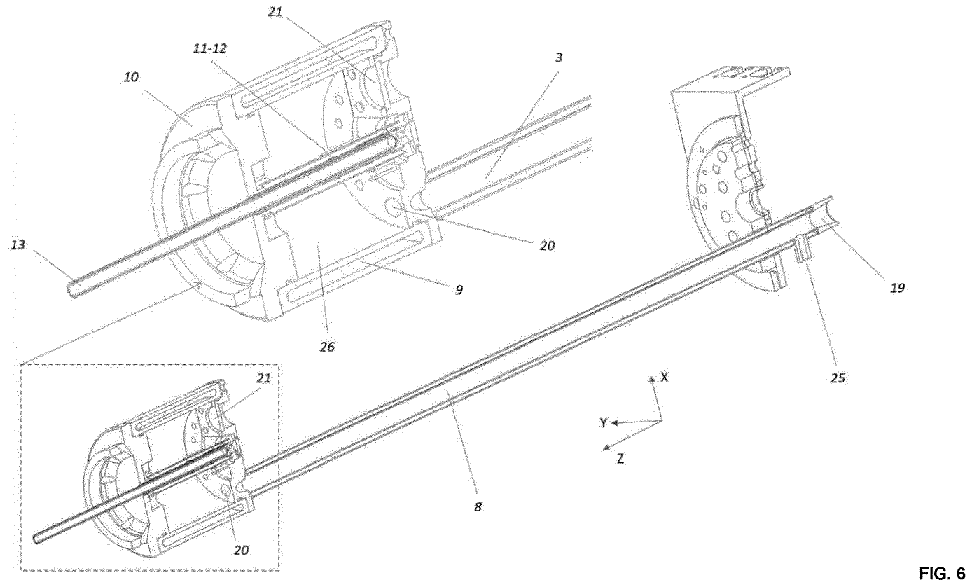

To additionally protect the sample from overheating, the probe head accommodates cooling units (8, 9, 10; 26) designed to deliver the cold N₂ gas to the sample. It consists of a glass dewar (8) and a thermally insulated sample chamber (26), The cold N₂ gas is injected into the dewar (8) via its inlet (25), is distributed inside the sample chamber (26) and removed away via the chamber outlet (10), preferable realized as an exhaust cup at the top of the chamber to provide a constant flow over the sample surface (see FIG. 6).

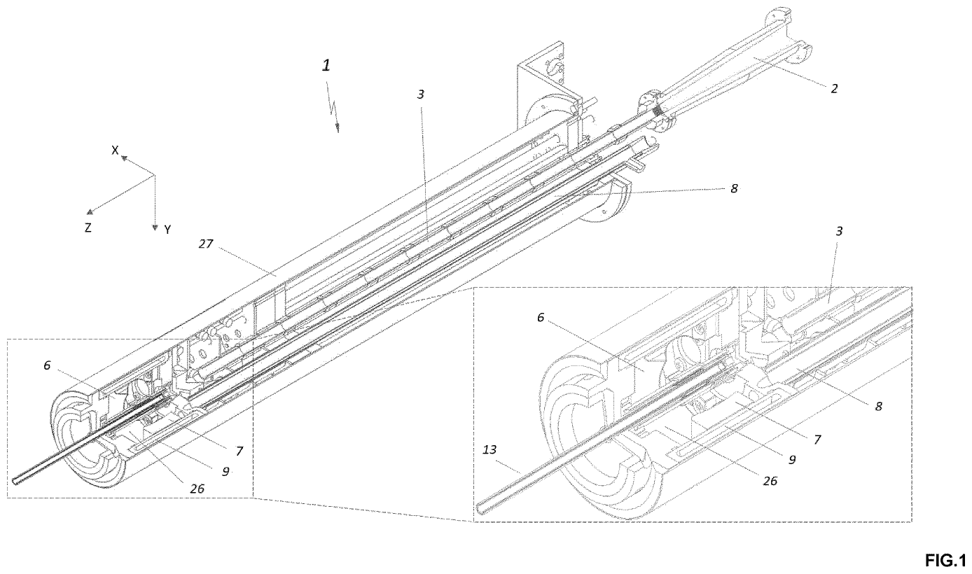

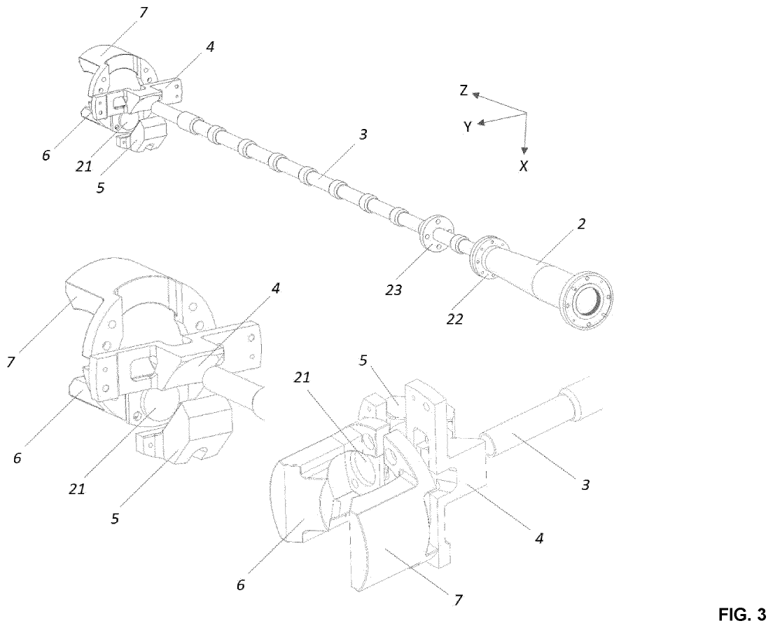

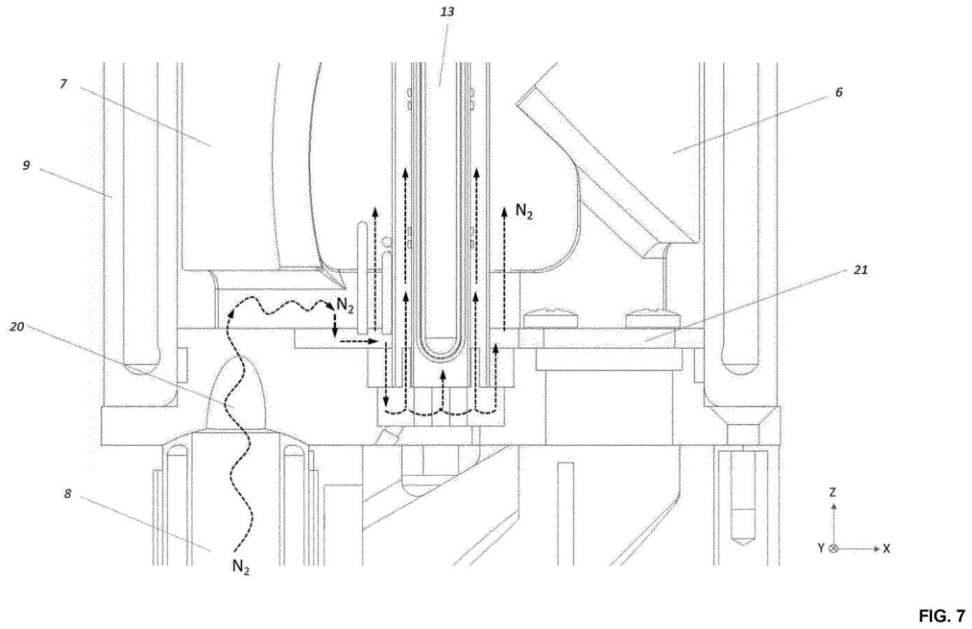

The general design of the DNP probe head (1) is presented in the FIG. 1. The cross section of the assembled probe head and the inset show details of the assembly. Further details of the main components are sketched in FIGS. 2-7.

The basic architecture of the probe head (1) can be described as a standard, liquid-state NMR probe head combined with the microwave components (2, 3, 4, 5, 6, 7) and a cooling system (8, 9, 10), to pump EPR transitions and to stabilize a sample temperature, respectively (see FIGS. 1-6).

For NMR detection, 2 (two) saddle coils (11, 12) are mounted around the sample assembly (13). The axis of the coils is perpendicular to the main magnetic field (B₀), which is oriented along the probe axis (axis Z). The larger coil (11) can be tuned to the resonance frequencies of ¹H and ¹⁹F (v=380-400 MHz). The second, smaller coil (12) is designed to be tuned at the resonance frequency of ¹³C (~100 MHz). It can be also tuned to frequencies of ²H (~61 MHz) and thus can be used for frequency-field locking. After minor modification of tuning circuits, matching to other NMR frequencies is feasible.

The central hollowed pillar of the probe head is formed by a corrugated waveguide (3), which is assembled from 11 shorter sections to form the total length of ~435.5 mm (see FIGS. 1-3). The WG sections are made of German Silver and corrugated with the corrugation parameters p=0.30 mm, d=0.28, w=0.15 mm, a=3.8 mm, where p, d, w and a are the period, groove depth, groove width and the waveguide inner radius, respectively. At the input side, the WG (3) is joined with the corrugated taper (2), which couples the WG with the transmission line from a microwave source. The input inner diameter of the taper is 19.3 mm. Whereas the output diameter is equal to the inner diameter of the corrugated WG (3), which is 7.6 mm.

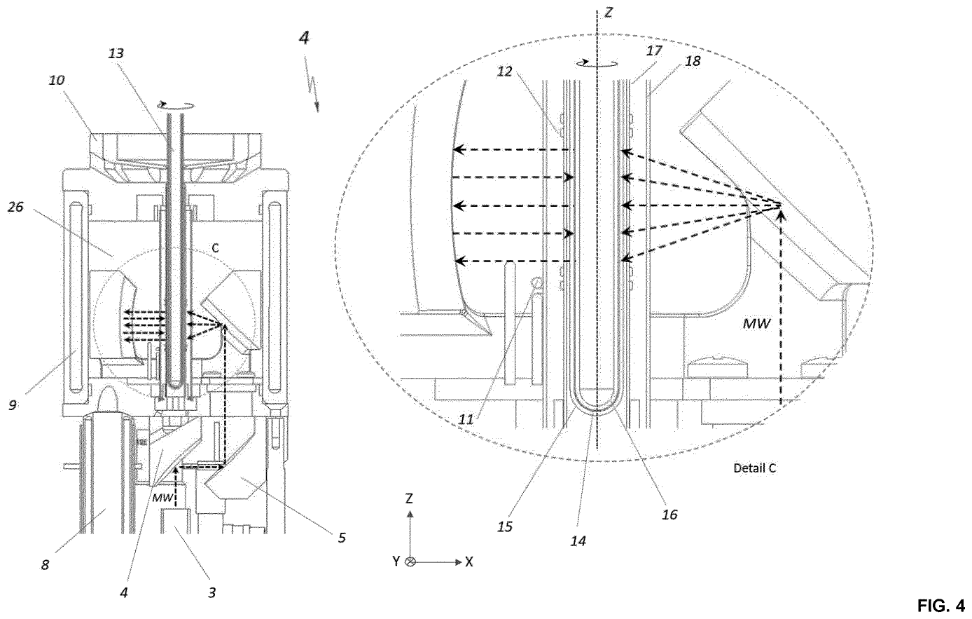

The microwave beam in the corrugated WG propagates as a hybrid HE₁₁-mode, thus at the output, it efficiently couples to the TEM₀₀ free-wave mode, which, in the form of a beam with an approximately Gaussian profile, is further guided to the sample by a system of three mirrors with curvatures based on conic sections (4, 5, 6). The mirrors are arranged in the way to expose the sample from the side to the mw beam (see FIG. 4). Mirror (4) and mirror (5) act to propagate the beam from the aperture of the WG and focus it to a beam waist between mirror (5) and mirror (6). The beam profile has approximately cylindrical symmetry throughout this beam path. Mirror (6) then refocuses the beam and reshapes the beam profile, focusing it to an elongated beam waist at the sample. This elongated profile covers the volume of the sample that produces an NMR signal more efficiently than a cylindrically symmetric beam. Furthermore, the mirrors are arranged in the way to keep the polarization of the input microwave, orientation of B₁ of which is perpendicular to the static magnetic field B₀, and thus to the Z axis (see FIG. 4). Finally, mirror (7) is positioned behind the sample volume and is used to reflect residual microwaves. Additional precautions were made to minimize cross-polarized components in the reflected beam, which is mainly defined by curvatures of the mirrors. In the preferred embodiment, the degree of the curvatures of the mirrors can be described by their focal lengths, which are 24.4 mm, 33.3 mm and 18.1 mm (maximum), for mirrors (4, 5, 6), respectively.

An important feature of the invention is that the mirror supports are made of Macor® ceramic, and only the reflecting surfaces are coated with gold. The thickness of the metallic layers is approximately 1 μm, that is several times larger than the skin layer in gold at 263 GHz (~0.15 μm). The approach was applied to minimize magnetic field inhomogeneities at the sample position, commonly introduced by metals deteriorating NMR resolution.

The sample tube assembly (13) is placed along Z axis and inside of the NMR coils (FIGS. 2 and 4). The sample arrangement is considered as another crucial subject of the invention. The liquid sample (14) is confined by two quartz tubes (15, 16) thus forming a thin layer with a thickness, which is chosen depending on the sample dielectric properties (see FIG. 4).

Imperatively, the layer thickness is below the mw penetration depth in the sample medium. In the preferred embodiment, the outer QZ tube (15) has dimensions of 4.97 mm (O.D.) and 4.21 mm (ID). The OD of the inner QZ tube (16) varies between 4.16 mm and 4.06 mm depending on the sample. The sample assembly (14, 15, 16; also referred as 13) rotates along Z axis (see FIG. 4), which is needed for two key reasons: 1) to increase the area of the sample being exposed to microwave, particularly to maximum B₁, and 2) to avoid overheating of the sample volume, which is under microwave irradiation. The first reason is particularly important since it represents a way to increase the sample volume under microwave, and its excitation homogeneity, and therefore, is also considered as a key approach of the invention. As the DNP irradiation time amounts to a few seconds, or in some experiments even continuous-wave irradiation, slow spinning of the sample tube at the frequency of about 20 Hz is applied in this embodiment. Rotation of the sample is performed using a standard capability of the commercial Bruker probe (Bruker Spinner). There are two other quartz tubes (17, 18) in the sample vicinity. They are implemented to stabilize the NMR coils and improve the cooling gas flow around the sample.

Implementation of a thin sample layer (14) confined by two quartz tubes (15, 16) allows keeping the layer thickness below the mw penetration depth. Furthermore, an important aspect of this configuration is the ability to increase the B₁-strength at the sample position on account of interferences at the interface of two dielectric media with different permittivity.

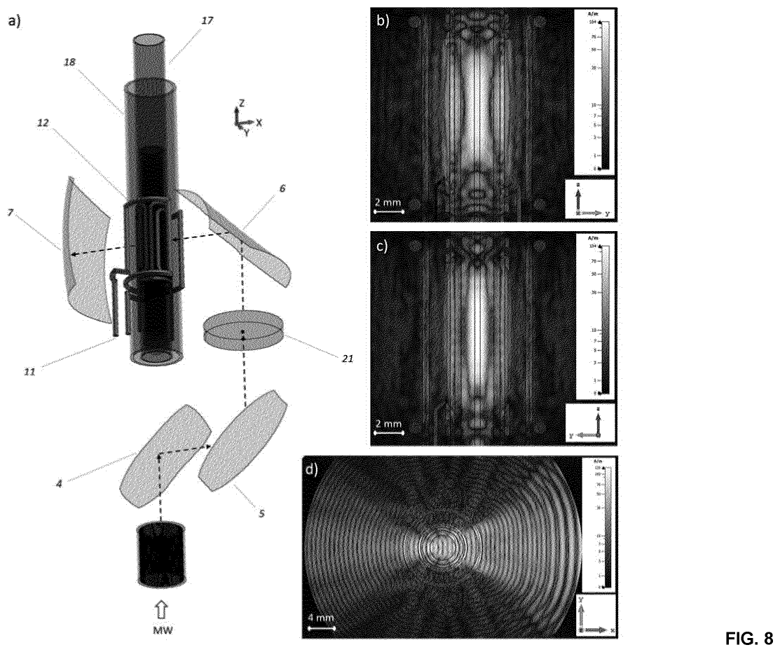

The microwave capabilities of the present embodiment were verified by finite-element numerical simulations using a CST Microwave Studio Suite™ 2019 (Dassault Systemes). For the simulations, a simplified model shown in FIG. 8(a) was applied. The model consisting of a corrugated WG section, mirrors (4, 5, 6, 7), PTFE window (21), NMR coils (11, 12), the sample assembly (13) and the shielding tubes (17, 18), was fed at the port of the WG section (mimicking the probe head input) by a linearly polarized Gaussian beam (TEM₀₀-mode). The input power of the Gaussian beam was set to 20 W. The mw polarization resembled the beam polarization provided by a microwave source (here, gyrotron). The simulations were performed to verify the design for a proper beam alignment, polarization and the beam transformation properties. Different solvents were used to evaluate sample-specific microwave losses and B₁ strengths in different sample points.

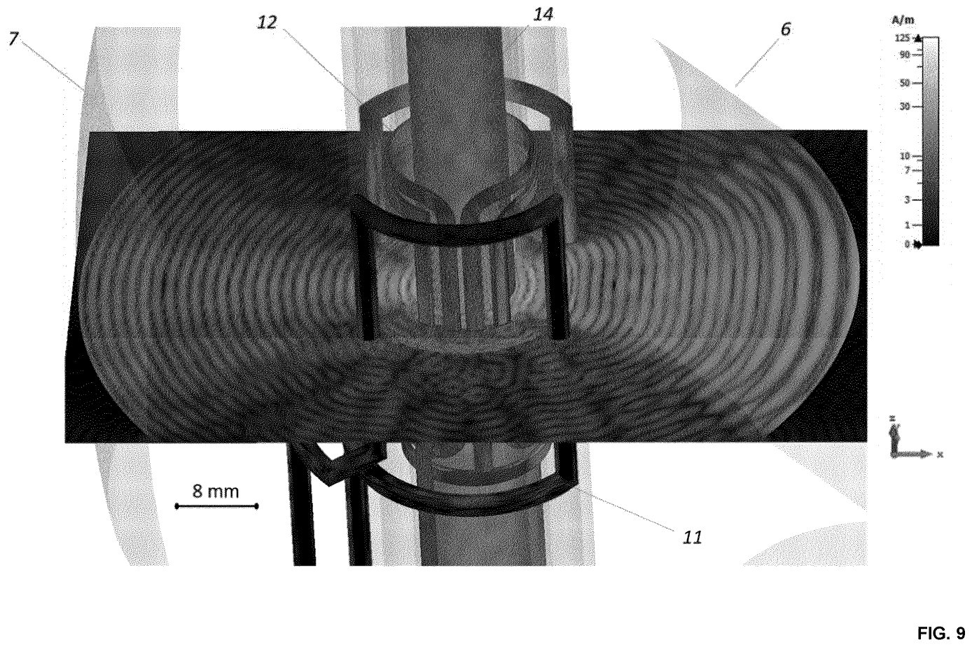

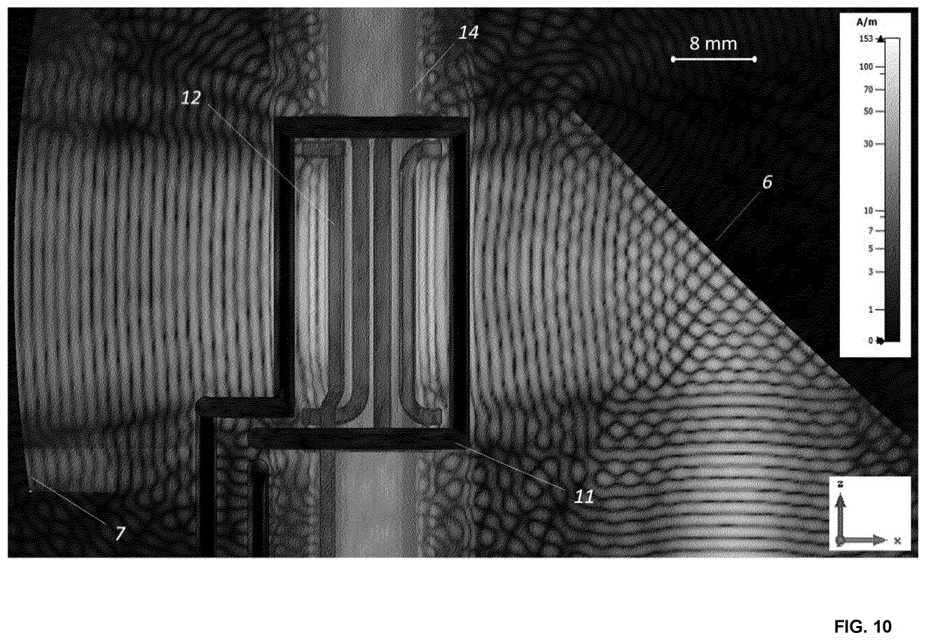

FIGS. 8(b,c) show the B₁-strength wave patterns at a particular phase instant (here, phase φ=0°), in the front- and the back-cut sections (YZ-plane) of the sample, respectively. The figures demonstrate the elongated field profile of the mw beam, as intended in order to expose the NMR active sample geometry. FIG. 8(d) shows the same simulation but in the XY-cut plane at the height point of the coils' centra along Z axis, whereas FIG. 9 shows the same cut as in FIG. 8(d), but at a different view angle better representing the coils arrangement with respect to the beam profile. The arrangement was explicitly designed to facilitate an efficient passage of the microwave to the sample (14). FIG. 10 represents this coil arrangement and the beam profile in the XZ-cut plane.

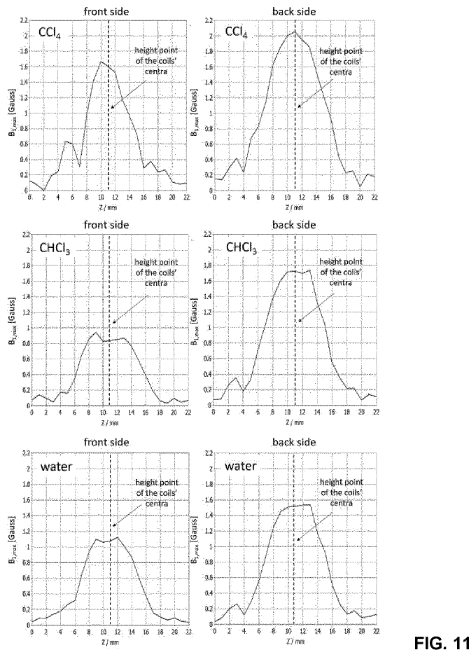

The graphs in FIG. 11 show the evaluated B₁-strength in the front- and the back-cut sections (YZ-planes, see for reference FIGS. 8(b,c)), and over the active sample height (0-22 mm) along Z axis, for three different solvents (CCl₄, CHCl₃, and water). The cut sections are orthogonal to the beam propagation, and made at the midpoints of the sample layers, thicknesses of which are 74 μm, 40 μm, and 25 μm for CCl₄, CHCl₃, and water, respectively. The simulations demonstrate that the mw arrangement of the probe head can afford effectively strong B₁ fields, close to the values needed to saturate PAs (≈2-3 G), but with reasonably high input power (≈20 W).

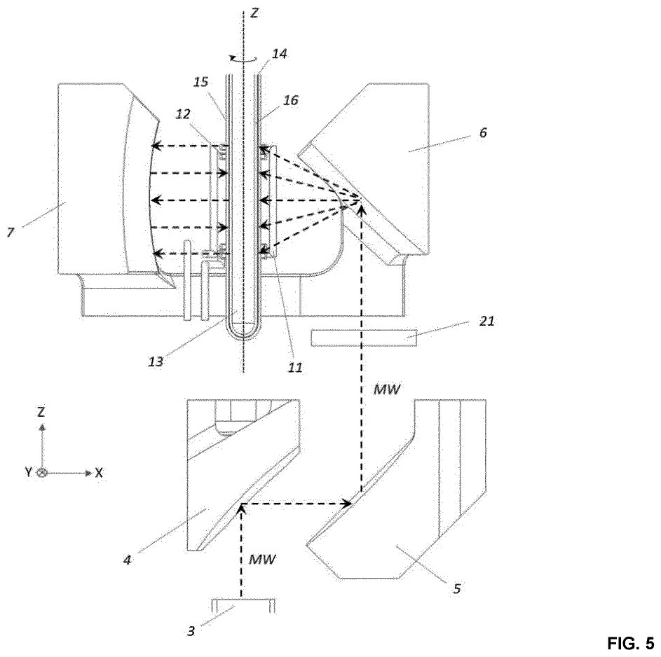

Another important feature of the invention is the cooling of the sample assembly (13) under microwave irradiation. The cooling units (8, 9, 10) are configured to deliver a cold N₂ gas to the sample position. It consists of a glass dewar (8) mounted parallel to the WG (axis Z) and a thermally insulated sample chamber (cryostat) (26), which encompasses the sample assembly (13) (see FIG. 5). The sample chamber (26) consists of a chamber glass dewar (9) and the outlet (10). The cold N₂ gas is injected into the inlet (25) of the transfer dewar (8), then through the entrance (20) into the cryostat to cool down the sample. The heated gas is then removed through the outlet (10) to provide a continuous gas flow in the sample area. The gas temperature at the inlet (20) can be stabilized and controlled in a broad range, which is 180-320 K for this invention, using a commercial Bruker VTU N₂-gas cooling unit. The cooling can also be achieved using a Bruker BCU, which does not require the use of a liquid N₂ evaporator. The PTFE window (21) is used to isolate the sample chamber and allow the microwave passage from mirror (5) to mirror (6).

The presented embodiment of the probe head has been tested on different samples with DNP experiments performed at nearly room temperature. The experiments were performed using a Bruker AVANCE Neo 400 MHz NMR console and a custom-built 263 GHz gyrotron as a microwave source. The samples were prepared by removing oxygen in a glove box and by freeze-pump-thaw cycles (4, 5) that efficiently remove O₂. The gyrotron frequency was set at resonance with the nitroxide low-field line.

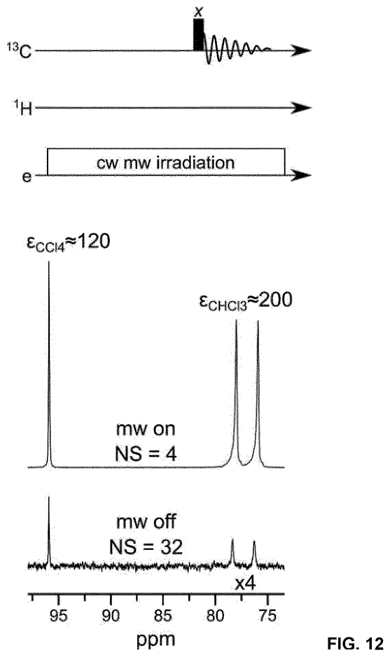

As the example, FIG. 12 shows the ¹³C NMR signal enhancements (s) obtained on the model system of 200 mM ¹³CHCl₃ in naturally-abundant CCl₄ doped with 10 mM ¹⁵N-d₁₆-4-oxo-TEMPO in an effectively irradiated sample volume of ~25 μL, and at the calibrated sample temperature of 300 K. The actual sample volume detectable by NMR, and needed to keep a high homogeneity, was ~40 μL. The upper inset in FIG. 12 shows the used pulse sequence for DNP. We observed ¹³C enhancements of ~120 (¹³CCl₄) and ~200 (¹³CHCl₃), and remarkably, no loss of NMR resolution. As the DNP irradiation was accomplished in a continuous-wave regime, spinning of the sample assembly (13) was applied (frequency 20 Hz). Furthermore, the sample temperature was controlled by the N₂ gas flow provided by the cooling units (8, 9, 10; 26). The experiment demonstrates that the mw components of the probe head do not perturb B₀-field homogeneity and the sample heating can be efficiently compensated by cooling. Therefore, the NMR lines under DNP excitation show significant enhancements and only limited broadening as compared to the lines in a standard, liquid-state NMR probe.

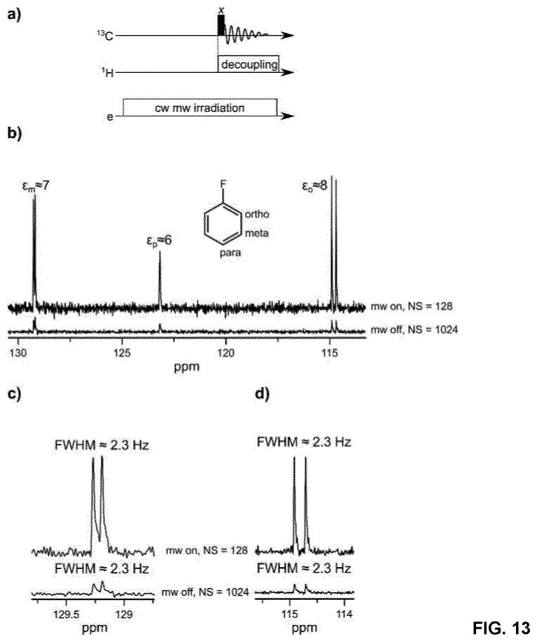

Another assessment of the NMR resolution is given in FIGS. 13(b,c,d), which display the enhanced (mw on) and the Boltzmann (mw off) spectra of ~500 mM natural abundance fluorobenzene doped with 25 mM ¹⁵N-d₁₆-4-oxo-TEMPO in CCl₄. FIG. 13(a) shows the applied pulse sequence. During the detection, the ¹H pre-saturation was performed for decoupling. The experiment demonstrates that both DNP and the Boltzmann spectra exhibit high NMR resolution (LW of ≈2.3 Hz), enabling detection of the weak J-couplings of ²JCF≈21 Hz and ³JCF≈7.9 Hz, respectively. The DNP experiment was performed with microwave power of ~43 W and the sample temperature was kept in the range of 290-310 K.

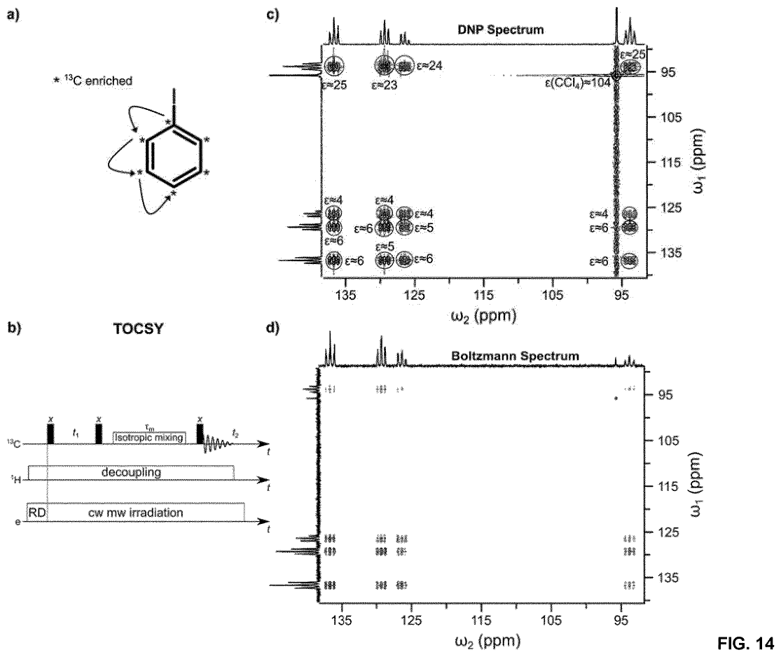

An important feature of any NMR setup is the ability to perform multi-dimensional experiments, which give insight into spin correlated interactions between adjacent nuclei. Such experiments are commonly performed over many hours, and stability of the experimental conditions, including sample temperature and its structural fidelity, is an important factor determining the outcome from the experiment. To verify this factor under DNP conditions, 2D Total Correlation (TOCSY) spectra on ¹³C₆-C₆H₅I (FIG. 14(a)) in CCl₄ doped with ~25 mM ¹⁵N-d₁₆-4-oxo-TEMPO were recorded. FIG. 14(b) depicts the pulse sequence for the experiment. In DNP-TOCSY, polarization transfer between adjacent nuclei occurs during a period of isotropic mixing (performed synchronously with the mw excitation), where a spin lock pulse train consisting of multiple π pulses is applied. The efficiency of this process is different for each cross peak and depends, first, on the DNP effect, and second, on the mixing time τₘ. In this experiment, DNP was performed under continuous-wave (cw) irradiation with mw power of ≈43 W, and τₘ was 20 ms. The sample temperature was kept in the range of ≈290-310 K. Furthermore, the ¹H-decoupling during both the DNP and the Boltzmann measurement was employed. FIGS. 14(c and d) show the DNP and the Boltzmann TOCSY spectra of ¹³C₆-C₆H₅I, respectively. Evidently, after DNP, ¹³C signal enhancements are observed for all diagonal- and cross peaks. Moreover, the observed enhancements are comparable to those obtained in corresponding 1 D experiments. This demonstrates that the stability of the experimental conditions is sufficient to perform 2D DNP experiments.

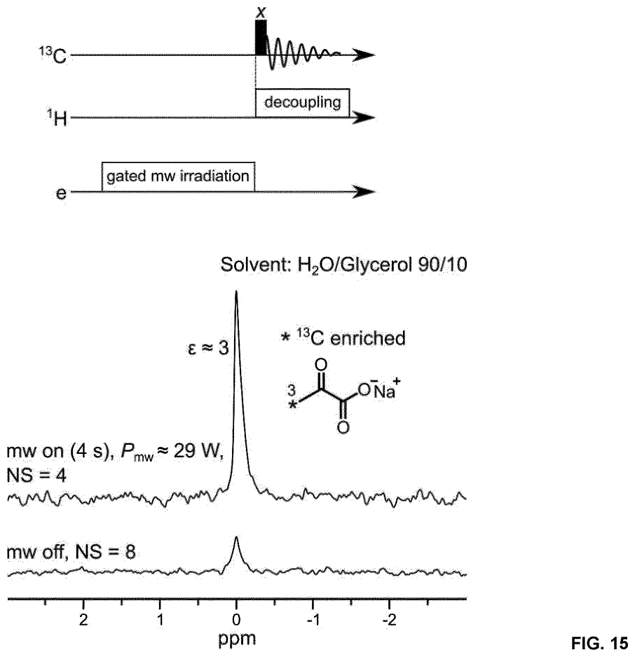

Finally, FIG. 15 demonstrates DNP on sodium pyruvate-3-¹³C in water:glycerol (9:1) mixed with 25 mM ¹⁵N-d₁₆-4-oxo-TEMPO. Due to high dielectric loses in water solvents, the sample layer and its volume were reduced to two times 25 μm (front- and back-side layer thicknesses) and ~8 μL, respectively. The DNP-NMR spectrum was recorded after 4 s excitation with ~23 W mw power at the pre-set sample temperature of 275 K and delivered the enhancement close to 3. The spectra show reasonably good linewidths, which are 9.6 Hz after DNP vs. 9.9 Hz in Boltzmann spectrum. Since pyruvate is a well-known component for tracking metabolism in cancer cells, it is important to provide the DNP-NMR capability for such kind of molecules, which however can efficiently be dissolved only in water. Our experiment shows that DNP in water is also feasible with the new probe head.

### SUMMARY

A dynamic nuclear polarization (DNP) probe head (1), suitable for high-resolution nuclear magnetic resonance (NMR) on liquid samples, comprising a corrugated waveguide (3), which transmits microwaves in a sub-mm wave range; four microwave mirrors (4, 5, 6, 7) further transmitting the microwaves to the sample (14), and designed in the way to spread the elongated microwave beam over the accessible sample area; and the cooling arrangement (8, 9, 10) to avoid heating of the sample and keep its temperature at particular level. The said sample (14) is confined between two concentric quartz (QZ) tubes (15, 16) and thus forms a thin, cylindrically shaped layer, which is below the penetration depth of the excitation microwave. This arrangement is referenced as a sample assembly (13); it is surrounded by NMR coils (11, 12) and possesses spinning capabilities to increase the sample area irradiated by the microwave and reduce the heating effect. Additionally, the NMR coils (12, 13) are arranged to allow for an efficient transmission of the microwave across the sample assembly (13).

### LIST OF REFERENCE NUMERALS

1 Probe head assembly
2 Corrugated downtaper
3 Corrugated waveguide assembly
4 Microwave mirror
5 Microwave mirror
6 Microwave mirror
7 Microwave mirror
8 N₂ gas flow dewar tube
9 Sample chamber dewar
10 Sample chamber exhaust cup
11 1^{st} RF coil
12 2^{nd} RF coil
13 Sample assembly (includes 14,15,16)
14 Liquid sample
15 Outer sample QZ tube
16 Inner sample QZ tube
17 Inner shielding QZ tube
18 Outer shielding QZ tube
19 N₂ gas temperature sensor/heater port
20 N₂ gas inlet (sample chamber)
21 Teflon window
22 Connecting flange
23 Connecting flange
24 Supporting base of the probe head
25 N₂ gas inlet (probe head)
26 Thermally isolated sample chamber
27 Probe head housing

### LIST OF PRIOR ART CITATIONS

The following publications have been considered for assessing patentability of the present invention:
[1] Overhauser, A. W., Polarization of Nuclei in Metals. Physical Review, 1953. 92(2): p. 411-415.
[2] Hausser, D. and D. Stehlik, Dynamic Nuclear Polarization in Liquids. Advances in Magnetic Resonance, 1968. 3: p. 79-139.
[3] Bennati, M. and T. Orlando, Overhauser DNP in Liquids on C-13 Nuclei. Emagres, 2019. 8(1): p. 11-18.
[4] Liu, G. Q., et al., One-thousand-fold enhancement of high field liquid nuclear magnetic resonance signals at room temperature. Nature Chemistry, 2017. 9(7): p. 676-680.
[5] Dai, D. H., et al., Room-temperature dynamic nuclear polarization enhanced NMR spectroscopy of small biological molecules in water. Nature Communications, 2021. 12(1).
[6] Dubroca, T., et al., Large volume liquid state scalar Overhauser dynamic nuclear polarization at high magnetic field. Physical Chemistry Chemical Physics, 2019. 21(38): p. 21200-21204.
[7] Orlando, T., et al., Dynamic Nuclear Polarization of C-13 Nuclei in the Liquid State over a 10 Tesla Field Range. Angewandte Chemie-International Edition, 2019. 58(5): p. 1402-1406.
[8] Levien, M., et al., Nitroxide Derivatives for Dynamic Nuclear Polarization in Liquids: The Role of Rotational Diffusion. Journal of Physical Chemistry Letters, 2020. 11(5): p. 1629-1635.
[9] Annino, G., et al., Magnetic resonance hyperpolarization and multiple irradiation probe head. 2016, U.S. Pat. No. 9,448,290B2.
[10] Prisner, T. and V. Denysenkov, Double-resonance structure and method for investigating samples by DNP and/or ENDOR. 2013, U.S. Pat. No. 8,570,033B2.
[11] Yoon, D., et al., High-Field Liquid-State Dynamic Nuclear Polarization in Microliter Samples. Analytical Chemistry, 2018. 90(9): p. 5620-5626.
[12] Denysenkov, V., D. H. Dai, and T. F. Prisner, A triple resonance (e, H-1, C-13) probehead for liquid-state DNP experiments at 9.4 Tesla. Journal of Magnetic Resonance, 2022. 337.
[13] Denysenkov, V. and T. Prisner, Liquid state Dynamic Nuclear Polarization probe with Fabry-Perot resonator at 9.2 T. Journal of Magnetic Resonance, 2012. 217: p. 1-5.
[14] Nevzorov, A. A., et al., Characterization of photonic band resonators for DNP NMR of thin film samples at 7 T magnetic field. Journal of Magnetic Resonance, 2021. 323.
[15] Soundararajan, M., et al., Proton-detected solution-state NMR at 14.1 T based on scalar-driven 13C Overhauser dynamic nuclear polarization. Journal of Magnetic Resonance, 2022. 343.
[16] Neugebauer, P., et al., Liquid state DNP of water at 9.2 T: an experimental access to saturation. Physical Chemistry Chemical Physics, 2013. 15(16): p. 6049-6056.
[17] Nevzorov, A. A., et al., Multi-resonant photonic band-gap/saddle coil DNP probehead for static solid state NMR of microliter volume samples. Journal of Magnetic Resonance, 2018. 297: p. 113-123.

1. A nuclear magnetic resonance (NMR) probe head for performing high-resolution, liquid-state dynamic nuclear polarization NMR (DNP-NMR) of a liquid sample medium, comprising:
a corrugated waveguide for microwave (mw) transmission, arranged along a longitudinal axis Z of the probe head,
a system of at least two mw reflecting mirrors for mw beam transmission, focusing and reshaping to match for a sample geometry,
at least one radio frequency (RF) coil for NMR detection mounted to allow mw passage to the sample area,
a cooling system comprising a flow dewar tube for feeding cryogenic fluid mounted on a side of the probe head and parallel to the corrugated waveguide and a thermally isolated sample chamber surrounded by a chamber dewar,
a sample spinning arrangement configured to achieve uniform irradiation over a sample volume, to increase the sample volume under mw irradiation, and to reduce sample heating, and
a sample assembly comprising concentric circular tubes or rods forming constraints for a sample layer.

2. The NMR probe head according to claim 1, wherein a thickness of the sample layer is between 0.25Δ and 1.25Δ, where Δ is a penetration depth of the mw in the liquid sample medium.

3. The NMR probe head according to claim 1, wherein the sample assembly comprises two concentric circular tubes or rods.

4. The NMR probe head according to claim 3, wherein the sample assembly is made of a material with low mw absorption.

5. The NMR probe head according to claim 1, wherein four of said mw reflecting mirrors are provided for transmitting the mw to the sample assembly while keeping a proper B₁ magnetic field polarization and forming a beam profile optimally distributed over a sample geometry to reduce its heating and increase an efficiency of mw excitation.

6. The NMR probe head according to claim 1, wherein the reflecting mirrors have curvatures based on conic sections.

7. The NMR probe head according to claim 1, wherein the system of mw reflecting mirrors comprises four mirrors positioned at respective distances of 17.25 mm, 42.5 mm, and 34.50 mm from the Z axis.

8. The NMR probe head according to claim 1, wherein the mirrors are manufactured from Macor® ceramic coated in a material that minimizes magnetic field distortions around the sample and keeping maintains a high homogeneity of the static magnetic field B₀.

9. The NMR probe head according to claim 8, wherein the gold coating of the mirrors has a thickness of between 3δ and 7δ, where δ is a skin depth in of gold at room temperature (~0.15 μm).

10. The NMR probe head according to claim 1, wherein the mirrors transmit the mw beam with a B₁ magnetic field polarization orthogonal to a static magnetic field, B₀, surrounding the sample to saturate ESR transitions for DNP, and to minimize magnetic field distortions around the sample.

11. The NMR probe head according to claim 1, wherein the at least one RF coil comprises two RF coils, one of which is matched for a second resonating frequency for measuring other nuclei or for ²H-locking.

12. The NMR probe head according to claim 1, further comprising at least one shielding tube is arranged concentrically around the sample assembly to conduct the cryogenic fluid.

13. The NMR probe head according to claim 1, wherein the corrugated waveguide is configured to minimize mw losses in a desired frequency range, to keep required polarization of the microwave magnetic field B₁, and to minimize B₀ magnetic field distortions around the sample.

14. The NMR probe head according to claim 1, wherein the cooling system further comprises a sample temperature control device that minimizes heating of the sample during mw excitation and stabilizes a temperature of the sample.

15. (canceled)
